(19) United States
(12) Patent Application Publication
(10) Pub. No.: US 2022/0413049 A1
(43) Pub. Date: Dec. 29, 2022

(54) Sensing a Switching State of an Electromechanical Switching Element

(71) Applicant: Siemens Schweiz AG, Zürich (CH)

(72) Inventor: Maximilian Tremmel, Regensburg (DE)

(73) Assignee: Siemens Schweiz AG, Zürich (CH)

(21) Appl. No.: 17/781,575

(22) PCT Filed: Dec. 3, 2020
(86) PCT No.: PCT/EP2020/084485

§ 371 Date: Jun. 1, 2022

(30) Foreign Application Priority Data
Dec. 5, 2019 (DE) 10 2019 218 919.9

(51) Int. Cl. G01R 31/327; H02H 3/04

(52) U.S. Cl. CPC G01R 31/3275; H02H 3/044

(57) ABSTRACT

Various embodiments of the teachings herein include a sensor facility for determining a switching state of an electromechanical switching element. The sensor facility may include: connection elements for electrically contacting respective connection contacts of the switching element; a coupling capacitor having two capacitor connections, wherein the first is coupled to a first connection element; a voltage generator providing a temporally variable electrical voltage, coupled to the second capacitor connection; a first overvoltage protection circuit coupled to a second connection element and blocking an electrical voltage greater than a maximum value of the temporally variable electrical voltage of the voltage generator; and a detector circuit coupled to the first overvoltage protection circuit and detecting electrical voltage to determine the switching state of the electromechanical switching element by evaluating the detected electrical voltage.

### CROSS-REFERENCE TO RELATED APPLICATIONS

This application is a U.S. National Stage Application of International Application No. PCT/EP2020/084485 filed Dec. 3, 2020, which designates the United States of America, and claims priority to DE Application No. 10 2019 218 919.9 filed Dec. 5, 2019, the contents of which are hereby incorporated by reference in their entirety.

### TECHNICAL FIELD

The present disclosure relates to switches. Various embodiments of the teachings herein include sensor facilities (e.g. sensor device or sensing device) and/or methods for determining a switching state of an electromechanical switching element, having at least two connection elements for electrically contacting two respective connection contacts of the electromechanical switching element.

### BACKGROUND

Sensor facilities and methods are used in the case of building automation and also in the case of analog switching technology, for example when determining a switching state of an electromechanical switching element, for example of an electromechanical switch that can be actuated manually, of an electromechanical button that can be actuated manually and/or the like. Electromechanical switching elements of this type are operated in general in a potential-free manner, in other words said electromechanical switching elements are electrically coupled using their at least two connections to the sensor facility. In this case, it is to be noted that the switching elements can be influenced using an arbitrary operating voltage, also called external voltage, for example a mains voltage of 230 V in the case of a frequency of approximately 50 Hz or the like.

In order to be able to detect the switching state of the electromechanical switching element, it is generally necessary that the switching element is influenced using an electrical current and a current flow through the switching element is detected. If the switching element is in the switched-off switching state, the current that is detected is essentially zero. Conversely, if the switching element is in the switched-on switching state, it is possible to detect a significant electric current that allows conclusions to be drawn about a low resistance loop impedance and consequently about the switched-on switching state of the switching element. If it is essentially not possible to detect a current despite the electrical voltage that is applied, it can be concluded therefrom that the switching element is in the switched-off switching state.

Electrical installations of this type, in particular in the field of building technology or building automation are realized using a field bus, for example in accordance with a KNX standard or the like. The KNX standard is a field bus for building automation. This standard is a successor of the field bus European Installation Bus (EIB), Batibus and also European Home Systems (EHS). With regard to the technology, the KNX standard is a development of the EIB, in particular by the addition of configuration mechanisms and also transmission media that have also been originally developed for the Batibus and EHS.

Even if these concepts have been proven, problems nevertheless remain. It has been shown to be disruptive in particular that during assembly the problem can occur that the connection elements of the sensor facility are not connected to the potential-free electromechanical switching elements but rather in lieu of this are inadvertently connected to non-isolated electromechanical switching elements. During commissioning, the sensor facility can then be influenced with a high electrical voltage that can lead to the sensor facility at least being damaged. Especially in the case of complex building installations, this is particularly disadvantageous.

### SUMMARY

The teachings of the present disclosure may be used to improve a sensor facility of the generic type and also a method of the generic type so that it is possible to reduce or to even completely avoid damage to the sensor facility in the event of an incorrect connection. As an example, some embodiments include a sensor facility (10) for determining a switching state of an electromechanical switching element (12), having: at least two connection elements (14, 16) for electrically contacting two respective connection contacts (18, 20) of the electromechanical switching element (12), characterized by at least one coupling capacitor (22) having a first and a second capacitor connection (24, 26), wherein the first capacitor connection (24) is electrically coupled to a first one of the connection elements (14), a voltage generator (28) so as to provide a temporally variable electrical voltage, wherein the voltage generator (28) is electrically coupled to the second capacitor connection (26), a first overvoltage protection circuit (30) that is electrically coupled to a second one of the connection elements (16) and said overvoltage protection circuit is designed so as to block an electrical voltage that has a value that is greater than a maximum value of the temporally variable electrical voltage of the voltage generator (28), and a detector circuit (32) that is electrically coupled to the first overvoltage protection circuit (30) and said detector circuit (32) is designed so as to detect electrical voltage and to determine the switching state of the electromechanical switching element (12) by evaluating the detected electrical voltage.

In some embodiments, the voltage generator (28) is designed so as to provide a temporal sequence of voltage pulses or an alternating current voltage (34).

In some embodiments, the voltage generator (28) has an energy storage device element (36) for storing electrical energy and a semiconductor switching element (38) that can be operated in a switching operation, wherein the voltage generator (28) is designed so as to electrically couple the energy storage device element (36) to the coupling capacitor (22) in dependence upon the temporally variable electrical voltage that is provided by the voltage generator (28) by the operation of the semiconductor switching element (38) in the switching operation.

In some embodiments, a second overvoltage protection circuit (40) is connected between the second capacitor connection (26) and the voltage generator (28) and said second overvoltage protection circuit (40) is designed so as to block an electrical voltage that has a value that is greater than a maximum value of the temporally variable electrical voltage of the voltage generator (28).

In some embodiments, at least the voltage generator (28) and the detector circuit (32) are connected to an EIB bus (42).

In some embodiments, at least one inductance is connected between the first connection element (14) and the voltage generator (28).

As another example, some embodiments include a method for determining a switching state of an electromechanical switching element (12) including: providing a temporally variable electrical voltage by means of a voltage generator (28), influencing a first connection contact (18) of the electromechanical switching element (12) with the temporally variable electrical voltage via at least one coupling capacitor (22), detecting an electrical voltage of a second connection contact (20) of the electromechanical switching element (12) by means of a detector circuit (32) via a first overvoltage protection circuit (30) that is designed so as to block an electrical voltage that has a value that is greater than a maximum value of the temporally variable electrical voltage of the voltage generator (28), and determining the switching state of the electromechanical switching element (12) by means of the detector circuit (32) by evaluating the detected electrical voltage.

In some embodiments, at least the voltage generator (28) and the detector circuit (32) use a uniform electrical reference potential.

In some embodiments, the voltage generator (28) provides a square wave voltage.

In some embodiments, the temporally variable electrical voltage is selected in such a manner that a contamination of at least one contact element that is electrically connected to one of the connection contacts (18, 20) is at least in part removed.

### BRIEF DESCRIPTION OF THE DRAWINGS

Further effects and features are apparent in the following description of exemplary embodiments with reference to the attached figures. In the figures, identical reference numerals refer to identical features and functions. In the drawings:

FIG. 1 shows a schematic block diagram of a sensor facility, which is connected to an EIB bus, for determining switching states of a plurality of switches that are connected to the sensor facility and can be actuated manually;

FIG. 2 shows a schematic block diagram of the sensor facility in accordance with FIG. 1;

FIG. 3 shows a schematic block diagram as in FIG. 2, wherein however details of a voltage generator and a detector circuit are illustrated;

FIG. 4 shows a schematic circuit diagram for a voltage generator in accordance with FIG. 3;

FIG. 5 shows a schematic circuit diagram for a first overvoltage protection circuit in conjunction with a detector circuit in accordance with FIG. 3,

FIG. 6 shows a schematic diagram of signals that are generated using the circuits in accordance with FIGS. 4 and 5; and

FIG. 7 shows a schematic diagram of signals as in FIG. 6, wherein an inductance is connected between the voltage generator and the first connection element.

### DETAILED DESCRIPTION

In some embodiments, a sensor facility has at least one coupling capacitor having a first and a second capacitor connection, wherein the first capacitor connection is electrically coupled to a first one of the connection elements, wherein the sensor facility moreover has a voltage generator so as to provide a temporally variable electrical voltage, wherein the voltage generator is electrically coupled to the second capacitor connection, wherein the sensor facility moreover has a first overvoltage protection circuit that is electrically coupled to a second one of the connection elements and said overvoltage protection circuit is designed so as to block an electrical voltage that has a value that is greater than a maximum value of the temporally variable electrical voltage of the voltage generator, and that the sensor facility has a detector circuit that is electrically coupled to the first overvoltage protection circuit and said detector circuit is designed so as to detect electrical voltage and to determine the switching state of the electromechanical switching element by evaluating the detected electrical voltage.

In some embodiments, a method includes: providing a temporally variable electrical voltage by means of a voltage generator, influencing a first connection contact of the electromechanical switching element with the temporally variable electrical voltage via at least one coupling capacitor, detecting an electrical voltage of a second connection contact of the electromechanical switching element by means of a detector circuit via a first overvoltage protection circuit that is designed so as to block an electrical voltage that has a value that is greater than a maximum value of the temporally variable electrical voltage of the voltage generator, and determining the switching state of the electromechanical switching element by means of the detector circuit by evaluating the detected electrical voltage.

The teachings of the present disclosure achieve an additional protection with respect to an incorrect connection of the sensor facility to electromechanical switching elements in that namely on the one hand it is possible using the coupling capacitor to achieve that the sensor facility can be protected against an effect on account of a large electrical potential at the first one of the connection elements or connection contacts and simultaneously the first overvoltage protection circuit can protect the detector circuit that is electrically coupled to the second of the connection elements or connection contacts. As a consequence, it is also possible owing to connection of the sensor facility to an electromechanical switching element that does not have any potential-free connection contacts to achieve an effective protection of the sensor facility against damage on account of an inadmissible electrical potential. Overall, the invention therefore renders it possible to improve the use of the sensor facility not only but particularly in the case of building automation, in particular in relation to a construction of a building installation, a change to the building installation and/or further improvements. An incorrect connection of the sensor facility to an electromechanical switching element that is not provided consequently no longer needs to lead to damage or to destruction of the sensor facility. As a consequence, in particular in relation to complex building installations it is possible to achieve a considerable improvement in reliability. The search for incorrect sensor facilities can as a consequence be omitted to a great extent.

Some embodiments are suitable in particular in conjunction with the use of field buses and it is possible to connect the sensor facility to said field buses. It is possible to achieve that a reaction on the corresponding field bus can be avoided to a great extent owing to the sensor facility in accordance with the invention. The sensor facility as such may be therefore not only better protected with respect to the prior art but rather said sensor facility furthermore also leads to an improved protection of a field bus that is connected to the sensor facility.

In some embodiments with a KNX building technology, for example, there is a universal device that can detect both voltages as well as closed current circuits. In particular, it is possible to achieve that the detector circuit is tolerant to a conventional operating voltage in buildings, for example approximately 230 V at approximately 50 Hz and can preferably remain essentially undamaged in the case of influence of this type. Simultaneously, it is possible with the invention to achieve that in the case of a corresponding voltage influence an accordingly large current flow and essentially also a dangerous state can be avoided.

The electromechanical switching element can be for example a switch that can be actuated manually, a button that can be actuated manually, a switch having a toggle function that can be actuated manually, additional contact pairs for additional functionalities and/or the like. For this reason, the electromechanical switching element can naturally also be a rotary switch, in particular a rotary switch that can be actuated manually. The switching element however does not need to be a switching element that can only be actuated manually. Naturally, the electromechanical switching element can also be actuated by means of a suitable drive facility, for example in the case of a contactor, a relay, combination circuits and/or the like.

The electromechanical switching element comprises at least two respective connection contacts and the electromechanical switching element can be electrically coupled to the sensor facility. It is preferred that each of the connection contacts is connected to a corresponding contact element of the electromechanical switching element with the result that the respective switching function can be provided between the at least two connection contacts. The switched-off switching state therefore for example in the case of an electromechanical switching element having two connection contacts in general is characterized by virtue of the fact that an electrical connection is not provided between these two connection contacts because the corresponding contact elements in the switched-off switching state are positioned spaced from one another. Conversely, in the switched-on switching state, the contact elements contact one another with the result that a low resistance electrical connection is provided between the connection contacts. It is preferred that the state relates to a respective pair of allocated connection contacts having the respective contact elements.

The coupling capacitor is an electronic component that provides an electrical capacitance. The capacitance of the coupling capacitor can be for example in a range of approximately 100 pF to approximately 1000 nF. As a consequence, it is possible to achieve that the reactance increases with the result that the current flow reduces. In the event of failure, it is possible in the case of influencing using mains voltage that the current flow is so low that the device interior could even be touched although a mains voltage is applied. The coupling capacitor is designed for a dielectric withstanding voltage or a rated voltage that is oriented to the maximum possible voltage that can occur during use. In building technology, this is in general an alternating current voltage of approximately 230 V at approximately 50 Hz. For the coupling capacitor, it is preferably proposed that this coupling capacitor has a specification X1 or Y2 as is typically also provided for capacitors that are also used in radio interference filters to suppress interference of electrical lines. These specifications are subject to standardization which is why further embodiments are foreseen in this regard. The coupling capacitor is preferably designed as a ceramic capacitor or as a film capacitor. Naturally, combinations thereof can also be provided. The coupling capacitor can also comprise multiple capacitor components. For this reason, it is possible to provide a respective coupling capacitor for each connection element.

The connection elements can comprise connection lines that can have connection lugs on the end for connecting to the electromechanical switching element and said connection lugs can be electrically and mechanically connected to the corresponding connection contacts of the electromechanical switching element.

For this reason, it is however also possible to provide that the connection lines are directly electrically coupled to the connection contacts, for example by means of a connecting technology such as soldering, welding, adhesive bonding, clamping and/or the like. The connection elements can comprise lines that are only a few cm long. Furthermore, the connection elements can however also have lines that are up to approximately 100 m long or even more. Naturally, the at least two connection elements do not need to be of an identical length and can provide different lengths or connection possibilities depending upon the construction.

The coupling capacitor has a first capacitor connection and a second capacitor connection. In general, the capacitor connections can be designed as essentially mechanically and/or electrically identical. Depending on the requirement and construction, it is also possible however for said capacitor connections to differ from one another. The first capacitor connection is electrically coupled to a first one of the connection elements. The second capacitor connection is conversely electrically coupled to the voltage generator so as to provide the temporally variable electrical voltage. As a consequence, the voltage generator is not directly connected to the first connection element with the result that the voltage generator in the case of an incorrect influencing of the first connection element using an undesirably high electrical potential can be protected by the coupling capacitor, for example owing to a current-limiting effect of the coupling capacitor such as for example its reactance.

Simultaneously, this allows the coupling capacitor to provide a corresponding electrical voltage to the electromechanical switching element owing to the temporally variable electrical voltage of the voltage generator with the result that it is possible using the detector circuit to determine the switching state of the electromechanical switching element.

The voltage generator can comprise an electronic circuit that can be designed for example as a hardware circuit also in combination with a computer unit or the like. The voltage generator provides the temporally variable electrical voltage in a predeterminable manner and the voltage generator can have a setting unit for this purpose. It is therefore possible for example to provide that an amplitude, a frequency, a voltage form and/or the like can be set. For this reason, it is possible for at least some of these parameters however to also be at least in part fixedly predetermined, for example by a corresponding design of the hardware circuit or the like.

The first overvoltage protection circuit is electrically coupled to the second of the connection elements or is connected to said second of the connection elements. In some embodiments, the first overvoltage protection circuit comprises a hardware circuit that is designed so as to block an electrical voltage that has a value that is greater than a maximum value of the temporally variable electrical voltage of the voltage generator.

Blocking in this context means not only that an electrical voltage can be interrupted but rather in particular also that the electrical voltage can be limited to a value that is predetermined by the first overvoltage protection circuit. For this purpose, it is possible to provide corresponding electronic components, for example suppressor diodes, Zener diodes, protective resistors, combination circuits thereof and/or the like. It is preferred that the first overvoltage protection circuit only then engages or is then only active if a voltage is provided that is greater than a maximum possible voltage of the voltage generator. As a consequence, it is possible to achieve that the first overvoltage protection circuit is essentially not active in the intended operation and consequently the function of the sensor facility is essentially not impaired if the switching state of the electromechanical switching element is determined by the sensor facility. For this purpose, it is possible to provide that the first overvoltage protection circuit is set in dependence upon characteristics of the voltage generator.

Moreover, the detector circuit is electrically coupled to the first overvoltage protection circuit. The detector circuit is designed so as to detect an electrical voltage and so as to determine the switching state of the electromechanical switching element by evaluating the detected electrical voltage. For this purpose, an electronic circuit, for example according to the type of hardware circuit and/or computing unit, can be provided and said electronic circuit is capable in particular of determining the switching state from a temporal curve of the detected electrical voltage. For this reason, it is however also only possible to provide a static evaluation of the detected electrical voltage in that for example the detected electrical voltage is compared with a voltage comparison value, wherein a value of the detected electrical voltage that is greater than the voltage comparison value represents the switched-off switching state, whereas a smaller value of the detected electrical voltage than the voltage comparison value represents the switched-on switching state. In this case, the voltage comparison value can preferably be defined in such a manner that also transition resistances that can occur in the switched-on switching state of the switching element for example between the contact elements are taken into consideration or the like. The detection of the electrical voltage can comprise the detection of a voltage amplitude, a voltage form, a frequency and/or the like. As a consequence, it is possible to achieve an almost 100% immunity against incorrect detection because in general malfunctions do not have identical signal forms and also clocking frequencies.

In some embodiments, the detector circuit provides a signal that represents the determined switching state of the electromechanical switching element. Such a signal can be for example an analog electrical signal, for example an electrical voltage, an electrical current or the like. Furthermore, the signal can naturally also be a digital signal, for example a binary coded signal that represents the switching state.

In some embodiments, the voltage generator is designed so as to provide a temporal sequence of voltage pulses or an alternating current voltage. The temporal sequence of voltage pulses can comprise for example a final number of voltage pulses. Naturally, it is also possible to provide that the sequence of voltage pulses is not temporally limited. The voltage pulses can essentially be designed as identical. Naturally, the voltage pulses can also be designed differently from one another, for example with regard to their amplitude, their pulse width and/or the like.

The voltage pulses can moreover have a predeterminable flank steepness, for example at the start and/or at the end of a respective voltage pulse. In some embodiments, the voltage pulses are temporally spaced at least in a temporal interval of approximately 700 μs, approximately 150 μs, or 100 μs with respect to one another. Naturally, the temporal interval of two directly consecutive voltage pulses can also be selected as smaller. A duration of a respective voltage pulse can be for example approximately 70 μs or less, approximately 50 μs, 25 μs, or 10 μs. The time period of the pulse can be identical for all the pulses. The time period however does not need to be identical for all the pulses and can vary as required. In particular, it is possible to provide that pulse patterns such as for example bursts or the like can be formed by the voltage pulses.

In some embodiments, the alternating current voltage can be a pure alternating current voltage or also an alternating current voltage with a direct current voltage proportion. The alternating current voltage can be sinusoidal, triangular, sawtooth-shaped, rectangular and/or the like. In some embodiments, the amplitude of the alternating current voltage is temporally constant. Depending on the requirement, said amplitude can however also vary temporally. A frequency of the alternating current voltage is preferably greater than approximately 1.5 kHz, greater than approximately 5 kHz, or greater than approximately 10 kHz.

In some embodiments, the voltage generator has an energy storage device element for storing electrical energy and a semiconductor switching element that can be operated in a switching operation, wherein the voltage generator is designed so as to electrically couple the energy storage device element to the coupling capacitor in dependence upon the temporally variable electrical voltage that is provided by the voltage generator by the operation of the semiconductor switching element in the switching operation. As a consequence, it is possible in a simple manner to provide a voltage pulse sequence that is capable of realizing the desired function of the sensor facility.

The semiconductor switching element can have for example at least one transistor that is operated in the switching operation, in particular a field effect transistor, e.g. a metal oxide semiconductor field effect transistor (MOSFET) but also a bipolar transistor, in particular an insulated gate bipolar transistor (IGBT) or the like. Naturally, combination circuits of transistors, in particular different transistors, can also be provided, for example, in conjunction with further electronic components such as for example electrical resistors, electrical capacitors and/or the like. Furthermore, for this reason a thyristor can also be provided as a semiconductor switching element, in particular a gate turn off thyristor (GTO) or the like.

In relation to a semiconductor switching element, the use of a transistor means for the switching operation that in a switched-on switching state a particularly small electrical resistance is provided between the connectors of the transistor that form a switching path with the result that a high current flow is possible in the case of a very low residual voltage or particularly small voltage drop. Conversely, in a switched-off switching state the switching path of the transistor is high resistance, in other words said switching path provides a high electrical resistance with the result that also in the case of high electrical voltage that prevails at the switching path essentially no or only a particularly small, in particular insignificant, current flow is provided. A linear operation in the case of transistors differs from this.

In some embodiments, a second overvoltage protection circuit is connected between the second capacitor connection and the voltage generator and said second overvoltage protection circuit is designed so as to block an electrical voltage that has a value that is greater than a maximum value of the temporally variable electrical voltage of the voltage generator. For this reason, the second overvoltage protection circuit can be designed as similar or identical to the first overvoltage protection circuit. However, it is possible owing to the protective function of the coupling capacitor to achieve that the second overvoltage protection circuit can be simplified with respect to the first overvoltage protection circuit, for example in that said second overvoltage protection circuit comprises fewer components or the like. For example, the second overvoltage protection circuit can only comprise a single Zener diode or suppressor diode or the like. In this manner, the protective effect can be further improved with respect to the voltage generator, in particular if a particularly high electrical voltage having a high voltage steepness prevails at the first connection element. If namely the voltage steepness is particularly high, the protective effect of the coupling capacitor can be limited. It is possible owing to the second overvoltage protection circuit for the protective effect to be improved particularly in such a case with the result that overall the protective effect can be further improved for the voltage generator.

In some embodiments, at least the voltage generator and the detector circuit are connected to an EIB bus. As a consequence, it is possible to achieve that the sensor facility for a field bus can be used for the EIB bus and in this manner it is possible to improve a field bus based building installation. The embodiment is however not limited to use in EIB bus but rather can naturally equally be used in the KNX bus or the like. It is possible to supply the voltage generator with electrical energy from the field bus and simultaneously to transmit by means of the detector circuit the determined switching state of the electromechanical switching element via the field bus to a receiving site. For this purpose, the voltage generator and the detector circuit are designed accordingly. The voltage generator can comprise for this purpose a voltage supply circuit that renders it possible to supply energy to the voltage generator using energy from the EIB bus. The detector circuit can furthermore comprise signal processing that for example can have a computer unit in order to be able to output via the field bus in a suitable manner a corresponding signal that represents the determined switching state.

In some embodiments, the sensor facility has at least one inductance connected between the first connection element and the voltage generator. As a consequence, it is possible to improve additional effects in relation to the reliability of the detection of the switching state of the electromechanical switching element. Owing to the inductance, it is possible for example to achieve that when voltage pulses are used and also in the case of unsteady alternating current voltages such as for example a square wave voltage, an oscillation procedure is triggered that is capable of improving the reliability of the detection. The inductance can be designed as an electronic component. Naturally, the inductance can also be formed by multiple electronic components that can be looped in a suitable manner into the effective path. The inductance can also be formed for example at least in part by one or multiple external lines. Furthermore, the inductance can also be formed internally as a discrete component, for example as a fixed inductance, as an air coil, as a circuit board coil, combinations thereof or the like.

In some embodiments, at least the voltage generator and the detector circuit use a uniform electrical reference potential. As a consequence, a particularly simple and reliable sensor facility can be achieved. The reference potential can be for example a ground potential of the sensor facility.

In some embodiments, the voltage generator provides a square wave voltage. It is possible in a simple manner owing to the voltage generator to create the square wave voltage and it is possible in a likewise simple and reliable manner by means of the detector circuit to determine the square wave voltage from the detected electrical voltage.

In some embodiments, the temporally variable electrical voltage is selected in such a manner that a contamination of at least one contact element that is electrically connected to one of the connection contacts is at least in part removed. For this purpose, it can be provided that a particularly high number of voltage pulses having a preferably likewise high voltage steepness is provided with the result that overall a comparatively large current flow can be achieved via the contact elements of the electromechanical switching element. It is also possible for this reason to achieve the same with the alternating current voltage that has an accordingly high frequency. As a consequence, despite the coupling capacitor it is possible to achieve a comparatively large current through the contact elements if these contact elements come into physical contact with one another in the switched-on switching state with the result that possible contaminations, for example residue, corrosion or the like can be removed in that they for example burn off or the like. The reliability of the function of the sensor facility can consequently be further improved. A peak current that can be suitable is for example approximately 0.4 A or more, approximately 0.5 A, or approximately 1.1 A.

The advantages and effects that are described for the sensor facility incorporating teachings of the present disclosure also apply naturally in the same manner for the methods and vice versa. As a consequence of this, naturally apparatus features can also be worded as method features or vice versa.

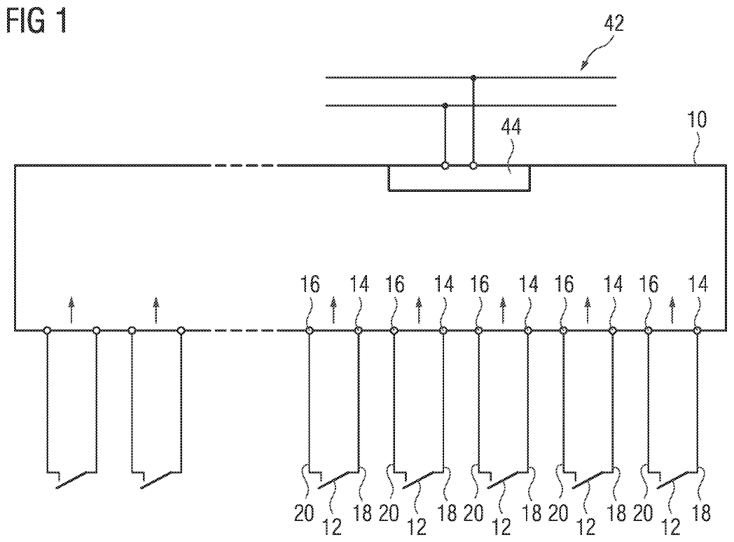

FIG. 1 illustrates in a schematic block diagram a sensor facility for determining switching states of switches 12 that are connected as electromechanical switching elements to the sensor facility 10 and can be actuated manually. In the present case, five manual switches 12 of this type are illustrated in an exemplary manner. However, it is also possible for an almost arbitrary number of manual switches 12 to be connected to the sensor facility 10. The sensor facility 10 is then designed accordingly.

Each switch 12 that can be actuated manually comprises two connection contacts 18, 20 and the switches 12 that can be actuated manually can be connected to the sensor facility 10 by means of said connection contacts 18, 20. Each of the switches 12 that can be actuated manually comprises contact elements that are not illustrated and are electrically connected to their respective connection contacts 18, 20. In a switched-on switching state, these contact elements are in mechanical contact with one another with the result that an electrical connection is provided between the respective connection contacts 18, 20 of the respective switch 12 that can be actuated manually. In a switched-off switching state, these contact elements are positioned spaced from one another with the result that an electrical connection is interrupted between the connection contacts 18, 20. The switch 12 that can be actuated manually can be designed for example as a rotary switch, as a toggle switch, as a button switch or the like. For this reason, the invention is however not limited to switches that can be actuated manually. It is likewise possible to provide that the switch 12 can be actuated by means of a drive facility, for example a pneumatic drive, an electric drive, a hydraulic drive or the like.

The sensor facility 10 comprises a bus unit 44 and the sensor facility 10 can be connected to an EIB bus 42 by means of said bus unit. As a consequence, the sensor facility 10 is particularly suitable for use in building automation. The sensor facility 10 determines the switching state of a respective switch of the manual switches 12 and outputs a digital signal in dependence upon the determined switching state via the EIB bus 42. The EIB bus 42 is simultaneously also used for the energy supply of the sensor facility 10, as is further explained below.

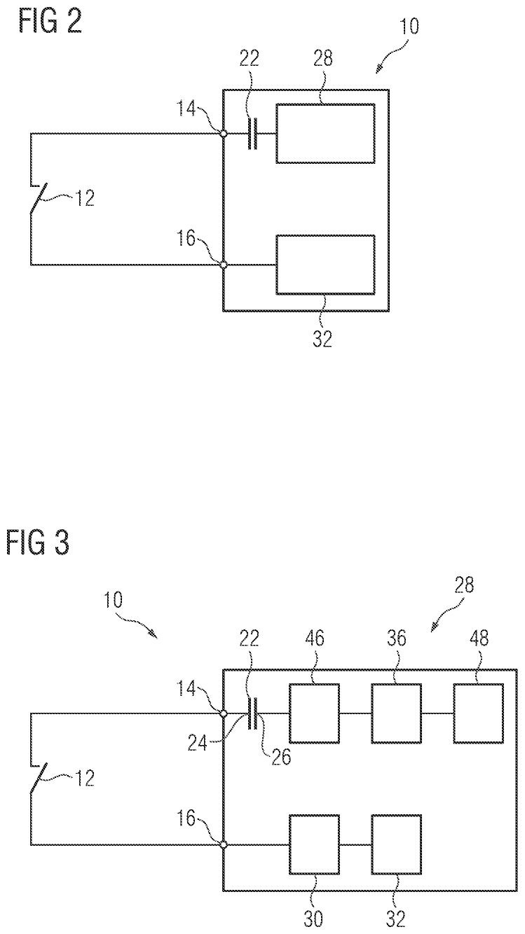

FIG. 2 illustrates in a schematic block diagram a rough schematic construction of the sensor facility 10. The sensor facility 10 comprises precisely two connection elements 14, 16 for one respective switch 12 that can be manually actuated and said connection elements are used so as to electrically contact the respective connection contacts 18, 20 of the respective switch 12 that can be manually actuated.

A voltage generator 28 is connected to a connection element 14 via a coupling capacitor 22. Conversely, a detector circuit 32 is connected to the connection element 16, however said detector circuit 32 is not directly connected to the connection element 16 as is explained more precisely below.

FIG. 3 illustrates a more detailed circuit diagram of the sensor facility 10 in accordance with FIG. 2. The voltage generator 28 comprises a voltage supply unit 48 that obtains electrical energy from the EIB bus 42—as explained above—and provides the voltage supply to the voltage generator 28. For this purpose, a buffer capacitor 36 is provided for the voltage supply unit 48 so as to store the electrical energy that is provided.

A clock generator 46 is connected to the buffer capacitor 36 and said clock generator 46 provides an essentially square wave form alternating current voltage as a temporally variable electrical voltage in a manner that can be predetermined. This square wave voltage is provided to a second capacitor connection 26 of the coupling capacitor 22 that is electrically coupled using its first capacitor connection 24 to the first connection element of the connection elements 14. As a consequence, a corresponding alternating current voltage is consequently available at the first connection element 14.

The capacitance of the coupling capacitor 22 is selected in such a manner that in the event of an incorrect connection of the contact element 14 to for example a connector that is influenced using an alternating current voltage of approximately 230 V at approximately 50 Hz the voltage generator 28 is essentially undamaged. The capacitor 22 in the present case is designed as an X1/Y2 safety capacitor and in the present case has a capacitance of approximately 680 pF. This can—depending on the application—also be selected differently.

A first overvoltage protection circuit 30 is connected to the second connection element 16 and said overvoltage protection circuit is designed so as to detect or to tap an electrical voltage at the connection element 16 and to limit a value of the detected electrical voltage. In the present case, it is provided that the detected electrical voltage is limited in such a manner that if the value of said electrical voltage is greater than a maximum value of the temporally variable electrical voltage of the voltage generator 28, said detected electrical voltage is limited to this value. Blocking in this case means therefore in particular limiting. In alternative embodiments, it can naturally be provided that the overvoltage protection circuit 30 does not permit any voltage in an activation case.

Moreover, a detector circuit 32 is connected to the first overvoltage protection circuit 30 and said detector circuit 32 is designed so as to evaluate the electrical voltage that is detected and consequently to determine the switching state of the respective manual switch 12. For this purpose, the detector circuit 32 comprises a computer unit that is not illustrated. The detector circuit 32 in the present case also comprises the bus unit 44 with the result that the detector circuit 32 can output a signal to the EIB bus 42 and said signal corresponds to a switching state that is determined.

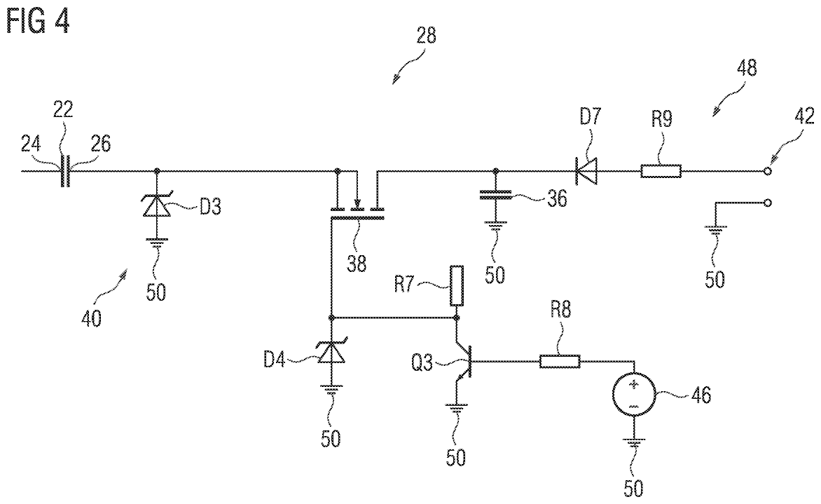

FIG. 4 illustrates in a schematic circuit diagram a possible construction of the voltage generator 28 in conjunction with the coupling capacitor 22. It is apparent that the coupling capacitor 22 is electrically coupled to its second capacitor connection 26 using a Zener diode D3 and said Zener diode is connected on its side using its opposite-lying connection to a ground potential 50 of the sensor facility 10. A second overvoltage protection circuit 40 is formed by the Zener diode D3.

The second capacitor connection 26 is moreover connected to a source connection, which is not illustrated, of a MOSFET 38 as a semiconductor switching element and the drain of said MOSFET is connected to the buffer capacitor 36 that is likewise connected using its opposite-lying connection to the ground potential 50. A Zener diode D4 is connected to a gate connection of the MOSFET 38 and said Zener diode is likewise connected using its opposite-lying connection to the ground potential 50 and consequently protects the gate connection of the MOSFET 38 against an overvoltage.

The clock generator 46 in the present case provides a square wave voltage having a frequency of approximately 10 kHz. The square wave voltage is supplied via a resistor R8 of a base of a bipolar NPN transistor that is operated in the grounded emitter circuit and said NPN transistor amplifies in a suitable manner this signal for influencing the gate connection of the MOSFET 38. It is not necessary to go into the details of the grounded emitter circuit because they are sufficiently known to the person skilled in the art.

Owing to the switching operation of the MOSFET 38, which is triggered by the square wave voltage and which is achieved in the manner described above, moreover as a consequence a corresponding alternating current voltage is provided at the first connection element 14.

The clock generator 46 is moreover connected to a voltage supply unit 48 that is designed so as to provide electrical energy from the EIB bus 42 for the operation of the clock generator 46. For this purpose, the EIB bus 42 is connected via a resistor R9 and a diode D7 to the buffer capacitor 36. As a consequence, it is possible to provide a direct current voltage from the operating voltage of the EIB bus 42 to the buffer capacitor 36 and said direct current voltage in the present case is approximately 30 V. This voltage is used so as to supply energy to the voltage generator 28, in other words also for the MOSFET 38. In alternative embodiments, this can naturally also vary. This direct current voltage in the present case is used so as to supply energy to all the components of the voltage generator 28.

Initially a capacitor C8 is connected to the second connection element 16 and the opposite lying connection of said capacitor is connected to the ground potential 50. As a consequence, it is possible to achieve an integrative effect in relation to the detected voltage at the second connection element 16. The capacitor C8 in the present case has a capacitance of approximately 100 nF.

Moreover, a first overvoltage protection circuit 30 is connected to the capacitor C8 and said overvoltage protection circuit is designed so as to block or to limit an electrical voltage that has a value that is greater than a maximum value of the electrical voltage that is provided by the voltage generator 28. For this purpose in the present case it is provided that initially a Zener diode D6 and then a series circuit of an electrical resistor R4 and a second Zener diode Dl is connected to the capacitor C8. This network renders it possible to reliably limit the voltage.

The detector circuit 32 is connected to a center tap of the series circuit of the electrical resistor R4 and the Zener diode Dl via a further electrical resistor R3 and the detector circuit in the present case is formed by a microprocessor as a computer unit. The microprocessor in the present case is likewise connected to the EIB bus 42, which is however not illustrated in the FIGURES. In other words, in the present case the microprocessor simultaneously also provides the functionality of the bus unit 44. As a consequence, it is possible owing to the microprocessor to evaluate the first electrical voltage at the second connection element 16 with the result that it is possible to determine the switching state of the switch 12 that can be actuated manually. It is not illustrated that in dependence upon the determined switching state of the switch 12 that can be actuated manually, the microprocessor outputs a corresponding digital signal that is adapted to the EIB bus 42.

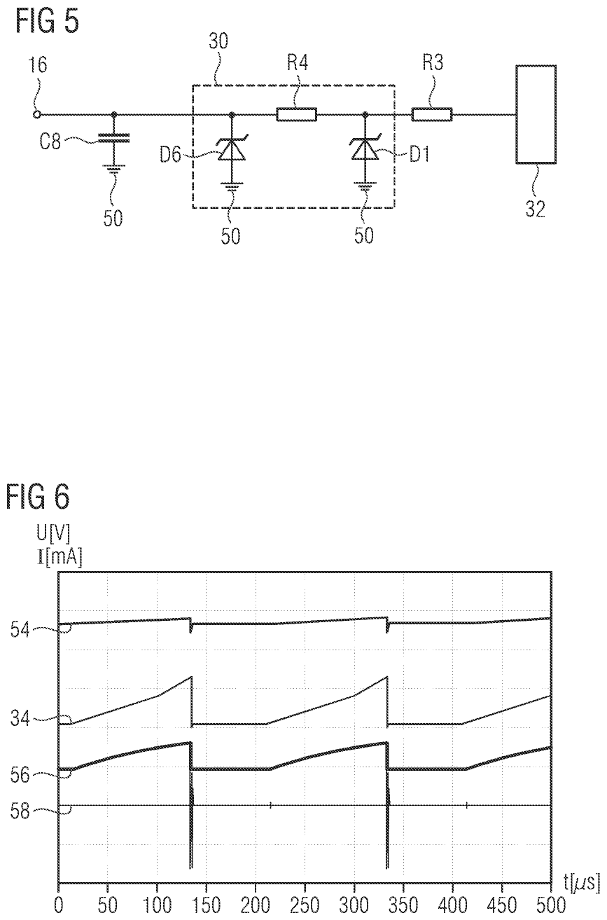

FIG. 6 illustrates in a schematic diagram the function of the sensor facility 10. The abscissa is allocated to the time, whereas the ordinate is allocated either to an electrical voltage or to an electrical current in dependence upon the illustrated graph that in each case is taken into consideration. In the diagram in accordance with FIG. 6 using a graph 54, an electrical voltage is illustrated at the capacitor upstream of the MOSFET 38. It is apparent from the diagram that the electrical voltage in the present case is approximately 30 V. Using a graph 34, a control signal is illustrated at the gate connection for the MOSFET 38. It is apparent from this that the control signal is not entirely square wave but rather is distorted on account of characteristics of the circuit. The square wave signal in this case consequently has a ramp. This is however overall not detrimental for the function of the circuit.

A corresponding voltage signal is illustrated with a graph 56 and said voltage signal is supplied to the detector circuit 32. It is apparent from FIG. 6 that the graph 56 with regard to a signal curve corresponds approximately to the graph 34. A current flow is illustrated using a graph 58 as said current flow can be detected by the detector circuit 32 with the voltage generator 28 in the switched-on switching state of the switch 12 that can be actuated manually. It is apparent that current pulses occur at points in time at which the graphs 34, 56 have flanks that are particularly steep. It is possible to evaluate this owing to the detector circuit 32 with the result that it is possible from this signal to determine the switching state of the manual switch 12.

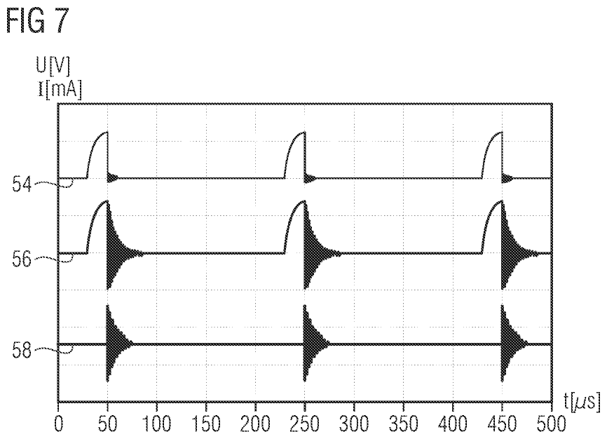

FIG. 7 illustrates in a further schematic diagram like FIG. 6 the conditions if the voltage generator 28 is not just connected via the coupling capacitor 22 to the first connection element 14 but rather in addition is also connected in series to a yet further inductance. It is apparent that in relation to the graphs 56 and 58 an enlarged oscillation procedure is generated that improves the detection by the detector circuit 32. The reliability of the detector circuit can therefore be increased.

In the exemplary embodiments that are illustrated in accordance with the FIGURES, the contact site of the switch 12 that can be actuated manually is influenced using an electrical peak current of approximately 200 mA, wherein the buffer capacitor 36 is however only charged using 0.75 mA, which means a charging power of less than approximately 20 mW. In the present embodiment, the comparatively large current flow is already achieved at a frequency of approximately 5 kHz owing to the rapid disconnection of the MOSFET 38. Since the frequency of the voltage generator 28 is however clearly higher, the reactance in particular of the coupling capacitor 22 reduces. The following example calculation is to illustrate this:

$$I ( 50 Hz ) = \frac{230 V}{2 π \cdot 50 Hz \cdot 47 nF} = 3.396 mA$$

In the above mentioned formula, it is apparent that at a mains frequency a comparatively small current flow via the coupling capacitor 22 is achieved. As a consequence, it is possible for the voltage generator 28 to be protected from damage on account of the mains voltage. Conversely, the function for determining the switching state by the invention proves to be particularly advantageous because said function, as is illustrated in the following formula, allows a comparatively large current flow via the contact elements of the switch 12 that can be actuated manually.

The following formula illustrates this:

$$I ( 10 kHz ) = \frac{30 V}{\frac{1}{2 π \cdot 10 kHz \cdot 47 nF}} = 88 mA$$

It is apparent that at the operating frequency of the voltage generator 28 at approximately 10 kHz, a comparatively large current, in the present case namely approximately 88 mA, can be supplied into the switch 12 that can be actuated manually even though the voltage generator 28 utilizes a considerably smaller voltage than the mains voltage. In the case of a suitable design of the circuit, in other words it is even also possible to achieve a free burning of contact surfaces of the switch 12 that can be actuated.

It is also possible with the invention in the case of particularly good detection characteristics of the detector circuit 32 to simultaneously provide a protective effect for the sensor facility 10 against overvoltages with the result that assembly errors that occur in particular in the case of building automation do not necessarily lead to damage or destruction of the sensor facility 10.

The exemplary embodiments are used solely to explain the teachings of the present disclosure and are not to limit the scope thereof.

### LIST OF REFERENCE NUMERALS

10 Sensor facility
12 Manual switch
14 First connection element
16 Second connection element
18 Connection contact
20 Connection contact
22 Coupling capacitor
24 First capacitor connection
26 Second capacitor connection
28 Voltage generator
30 First overvoltage protection circuit
32 Detector circuit
34 Alternating current voltage
36 Buffer capacitor
38 MOSFET
40 Second overvoltage protection circuit
42 EIB bus
44 Bus unit
46 Clock generator
48 Voltage supply unit
50 Ground potential
54 Electrical voltage
56 Graph
58 Graph
C8 Capacitor
Dl Zener diode
D3 Zener diode
D4 Zener diode
D6 Zener diode
D7 Diode
Q3 Transistor
R3 Resistor
R4 Resistor
R7 Resistor
R8 Resistor
R9 Resistor

What is claimed is:

1. A sensor facility for determining a switching state of an electromechanical switching element the sensor facility comprising:
two connection elements for electrically contacting two respective connection contacts of the electromechanical switching element;
a coupling capacitor having a first capacitor connection and a second capacitor connection wherein the first capacitor connection is electrically coupled to a first one of the connection elements;
a voltage generator providing a temporally variable electrical voltage, wherein the voltage generator is electrically coupled to the second capacitor connection;
a first overvoltage protection circuit electrically coupled to a second one of the connection elements and blocking an electrical voltage of a value greater than a maximum value of the temporally variable electrical voltage of the voltage generator; and
a detector circuit electrically coupled to the first overvoltage protection circuit and detecting electrical voltage to determine the switching state of the electromechanical switching element by evaluating the detected electrical voltage.

2. The sensor facility as claimed in claim 1, wherein the voltage generator provides a temporal sequence of voltage pulses or an alternating current voltage.

3. The sensor facility as claimed in claim 1, wherein the voltage generator includes:
an energy storage device element for storing electrical energy; and
a semiconductor switching element operable in a switching operation;
wherein the voltage generator electrically couples the energy storage device element to the coupling capacitor depending on the temporally variable electrical voltage provided by the voltage generator by the operation of the semiconductor switching element in the switching operation.

4. The sensor facility as claimed in claim 1, further comprising a second overvoltage protection circuit connected between the second capacitor connection and the voltage generator;
wherein said second overvoltage protection circuit blocks an electrical voltage having a value greater than a maximum value of the temporally variable electrical voltage of the voltage generator.

5. The sensor facility as claimed in claim 1, wherein the voltage generator and the detector circuit are connected to an EIB bus.

6. The sensor facility as claimed in claim 1, further comprising a inductance connected between the first connection element and the voltage generator.

7. A method for determining a switching state of an electromechanical switching element, the method comprising
providing a temporally variable electrical voltage using a voltage generator;
influencing a first connection contact of the electromechanical switching element with the temporally variable electrical voltage via a coupling capacitor;
detecting an electrical voltage of a second connection contact of the electromechanical switching element using a detector circuit via a first overvoltage protection circuit blocking an electrical voltage with a value greater than a maximum value of the temporally variable electrical voltage of the voltage generator, and
determining the switching state of the electromechanical switching element using the detector circuit by evaluating the detected electrical voltage.

8. The method as claimed in claim 7, wherein the voltage generator and the detector circuit use a uniform electrical reference potential.

9. The method as claimed in claim 7, wherein the voltage generator provides a square wave voltage.

10. The method as claimed claim 7, further comprising selecting the temporally variable electrical voltage to at least partially remove a contamination of at least one contact element electrically connected to one of the connection contacts.
